(19) United States
(12) Patent Application Publication
(10) Pub. No.: US 2025/0109502 A1
(43) Pub. Date: Apr. 3, 2025

(54) INHIBITOR COMPOUNDS FOR SELECTIVE PASSIVATION OF SURFACES

(71) Applicant: ENTEGRIS, INC., Billerica, MA (US)

(72) Inventor: Drew Michael Hood, Newtown, CT (US)

(21) Appl. No.: 18/900,619

(22) Filed: Sep. 27, 2024

Related U.S. Application Data
(60) Provisional application No. 63/541,678, filed on Sep. 29, 2023.

(51) Int. Cl. C23F 11/12

(52) U.S. Cl. CPC C23F 11/12

(57) ABSTRACT

Methods for selective passivation for metals and related systems and related methods are provided. A method comprises one or more of the following steps: exposing a substrate to an inhibitor compound to form a first layer on a metal surface of the substrate, wherein the inhibitor compound comprises an alkyne compound functionalized with at least one alkoxy group; and exposing the substrate to a precursor vapor to form a second layer on a non-metal surface of the substrate. Other methods and systems are provided herein.

### CROSS-REFERENCE TO RELATED APPLICATIONS

This application claims the benefit under 35 USC 119 of U.S. Provisional Patent Application No. 63/541,678, filed Sep. 29, 2023, the disclosure of which is hereby incorporated herein by reference in its entirety.

### FIELD

The present disclosure relates to inhibitor compounds for selective passivation of surfaces, and related systems and related methods.

### BACKGROUND

Precursors are deposited on surfaces of substrates. Precursors can be undesirably deposited on surfaces. When precursors are so deposited, the deposited precursors must be removed from those surfaces.

### SUMMARY

Some embodiments of the present disclosure relate to a method. In some embodiments, the method comprises one or more of the following steps: exposing a substrate to an inhibitor compound to form a first layer on a metal surface of the substrate; and exposing the substrate to a precursor vapor to form a second layer on a non-metal surface of the substrate. In some embodiments, the inhibitor compound comprises an alkyne compound functionalized with at least one alkoxy group;

Some embodiments relate to a composition. In some embodiments, the composition comprises an inhibitor compound. In some embodiments, the inhibitor compound comprises an alkyne compound functionalized with at least one alkoxy group. In some embodiments, the inhibitor compound in present in the composition at a purity of at least 95%. In some embodiments, the inhibitor compound is configured to selectively deposit a precursor vapor on a non-metal surface of a substrate.

Some embodiments relate to a method. In some embodiments, the method comprises one or more of the following steps: obtaining a substrate having at least one metal surface and at least one non-metal surface; exposing the substrate to the inhibitor compound comprising an alkyne compound functionalized with at least one alkoxy group; and depositing the inhibitor compound on the at least one metal surface of the substrate.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for selectively passivating a surface, according to some embodiments.

FIG. 2 is a flowchart of a method for selectively depositing an inhibitor compound, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbon compound having from 1 to 30 carbon atoms. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (tert-butyl), n-pentyl, iso-pentyl, tert-pentyl, n-hexyl, isohexyl, 3-methylhexyl, 2-methylhexyl, heptyl, octyl, nonyl, decyl, dodecyl, octadecyl, or any combination thereof.

As used herein, the term “alkenyl” refers to a hydrocarbon chain radical having from 1 to 10 carbon atoms and at least one carbon-carbon double bond. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbon chain radical having from 1 to 10 carbon atoms and at least one carbon-carbon triple bond. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “alkoxy” refers to a radical of formula —OR, wherein R is an alkyl, as defined herein. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, tert-pentoxy, or any combination thereof.

As used herein, the term “metal” refers to at least one of an alkali metal, an alkaline earth metal, a transition metal, a post-transition metal, a lanthanoid, an actinoid, or any combination thereof. In some embodiments, for example, the metal comprises or is selected from the group consisting of a transition metal. In some embodiments, the transition metal comprises or is selected from the group consisting of at least one of scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), or any combination thereof. In some embodiments, the metal is in ionic form, elemental form, or any combination thereof.

Some embodiments relate to inhibitor compounds for selective passivation of surfaces. In some embodiments, the inhibitor compounds provide for selective deposition of precursor materials on surfaces. In some embodiments, for example, the inhibitor compound selectively passivates a metal surface of a substrate. In some embodiments, the inhibitor compound does not passivate a non-metal surface of the substrate. In some embodiments, when the non-metal surface of the substrate is exposed to a precursor material, the precursor material is deposited on the non-metal surface. In some embodiments, the precursor material is not deposited on the metal surface of the substrate which remains passivated by the inhibitor compound. In some embodiments, the precursor material would deposit on the metal surface of the substrate in the absence of the inhibitor compound. In some embodiments, inhibitor compounds disclosed herein permit selective deposition of precursor materials on non-metal surfaces.

The inhibitor compounds and related systems and methods disclosed herein may be useful in the fabrication of microelectronic devices, including semiconductor devices, and the like. For example, the precursors materials can be used to form films or layers by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a composition. In some embodiments, the composition comprises an inhibitor compound.

In some embodiments, the inhibitor compound comprises an alkyne compound functionalized with at least one alkoxy group.

In some embodiments, the inhibitor compound is a compound of the formula:

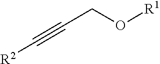

where:
R¹ comprises at least one of a C₁-C₁₀ alkyl, a C₁-C₁₀ alkenyl, or a C₁-C₁₀ alkynyl, or any combination thereof;
R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

In some embodiments, the inhibitor compound is a compound of the formula:

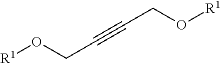

where:
R¹ independently comprises at least one of a C₁-C₁₀ alkyl, a C₁-C₁₀ alkenyl, or a C₁-C₁₀ alkynyl, or any combination thereof.

In some embodiments, the inhibitor compound comprises at least one of the following compounds:

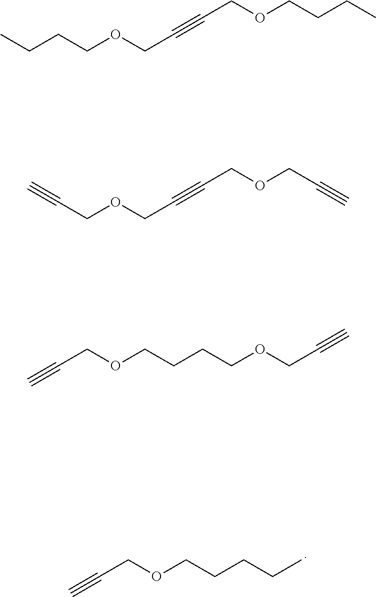

In some examples, the inhibitor compound is configured to selectively deposit a precursor vapor on a non-metal surface of a substrate.

In some embodiments, a composition comprises the inhibitor compound. In some embodiments, a vessel may comprise the composition. In some embodiments, a purity of the inhibitor compound present in the composition is at least 95%. In some embodiments, a purity of the inhibitor compound present in the composition is at least 50%, at least 55%, at least 60%, at least 65%, at least 70%, at least 75%, at least 80%, at least 85%, at least 90%, at least 91%, at least 92%, at least 93%, at least 94%, at least 95% or greater. In some embodiments, a purity of the inhibitor compound present in the composition is 95% to 99.9999%, 95% to 99.999%, 95% to 99.99%, 95% to 99.9%, 95% to 99%, 96% to 99%, 97% to 99%, 98% to 99%, 95% to 98%, 95% to 97%, 95% to 96%, 98% to 99.9%, 99% to 99.9%, 99% to 99.99% 99% to 99.999%, 99% to 99.9999%, or any range or subrange between 95% to 99.9999%.

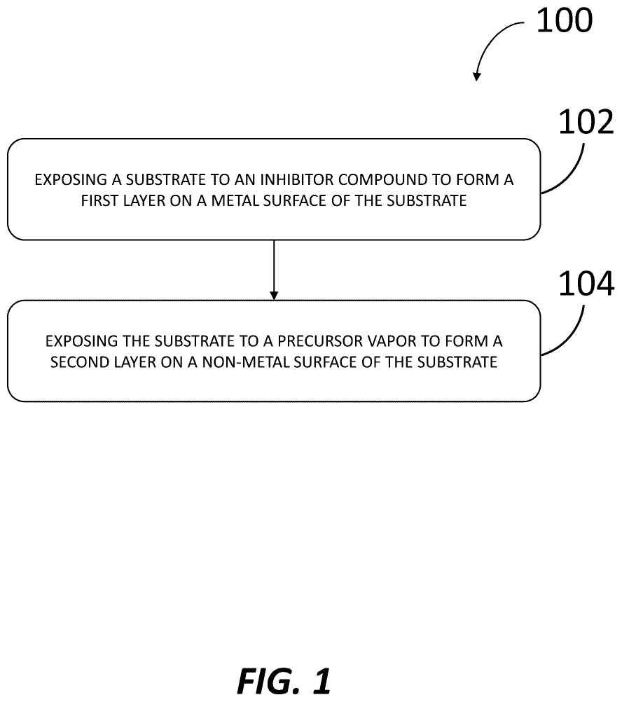

FIG. 1 is flowchart of a method 100 for is a method for selectively passivating a surface, according to some embodiments. As shown in FIG. 1, the method 100 for selectively passivating a surface comprises one or more of the following steps: exposing 102 a substrate to an inhibitor compound to form a first layer on a metal surface of the substrate; and exposing 104 the substrate to a precursor vapor to form a second layer on a non-metal surface of the substrate.

At step 102, in some embodiments, the method 100 comprises exposing a substrate to an inhibitor compound to form a first layer on a metal surface of the substrate.

In some embodiments, the inhibitor compound comprises an alkyne compound functionalized with at least one alkoxy group.

In some embodiments, the inhibitor compound is a compound of the formula:

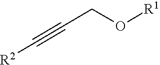

where:
R¹ comprises at least one of a C₁-C₁₀ alkyl, a C₁-C₁₀ alkenyl, or a C₁-C₁₀ alkynyl, or any combination thereof;
R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

In some embodiments, the inhibitor compound is a compound of the formula:

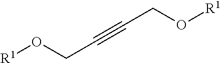

where:
R¹ independently comprises at least one of a C₁-C₁₀ alkyl, a C₁-C₁₀ alkenyl, or a C₁-C₁₀ alkynyl, or any combination thereof.

In some embodiments, the inhibitor compound comprises at least one of the following compounds:

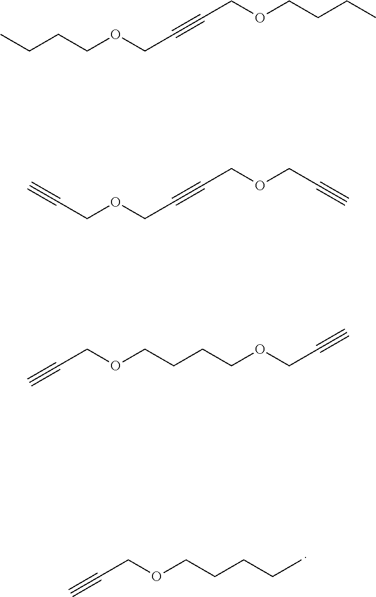

In some examples, the inhibitor compound is configured to selectively deposit a precursor vapor on a non-metal surface of a substrate.

It will be appreciated that nay of the inhibitor compounds disclosed herein may be employed without departing from the scope of this disclosure.

In some embodiments, the exposing comprises contacting the substrate with the inhibitor compound. In some embodiments, the contacting refers to bringing the substrate and the inhibitor compound into close or immediate proximity. In some embodiments, the contacting refers to bringing the substrate and the inhibitor compound into directly physical contact. In some embodiments, the exposing comprises introducing the inhibitor compound into a chamber containing the substrate. In some embodiments, the exposing comprises pumping the inhibitor compound from one location to a chamber containing the substrate. In some embodiments, the exposing comprises supplying the inhibitor compound to the substrate. In some embodiments, the exposing comprises vaporizing the inhibitor compound. In some embodiments, the exposing comprises flowing the inhibitor compound from one location to a chamber containing the substrate. In some embodiments, the exposing comprises feeding the inhibitor compound to a chamber containing the substrate. In some embodiments, exposing the substrate to the inhibitor compound comprises pulsing the inhibitor compound into a chamber containing the substrate.

The substrate may have at least one metal surface. As used herein, a metal surface refers to a surface comprising metal. In some embodiments, the at least one metal surface of the substrate comprises or is formed of a metal component. In some embodiments, the metal component comprises at least one of an elemental metal, a metal alloy, a metal composite, a metal mixture, a metal compound, a metal salt, or any combination thereof. In some embodiments, the metal component comprises a metal. In some embodiments, the metal comprises an alkali metal. In some embodiments, the metal comprises an alkaline earth metal. In some embodiments, the metal comprises a transition metal. In some embodiments, the metal comprises a post-transition metal. In some embodiments, the metal comprises a lanthanoid. In some embodiments, the metal surface comprises at least one of copper, tungsten, cobalt, ruthenium, or any combination thereof.

The substrate may have at least one non-metal surface. As used herein, a non-metal surface refers to a surface not comprising metal. In some embodiments, the at least one non-metal surface of the substrate comprises or is formed of a non-metal component. In some embodiments, the non-metal component comprises a dielectric material. In some embodiments, the non-metal component comprises an insulating material. In some embodiments, the non-metal component comprises a low dielectric constant material. In some embodiments, ceramic material. In some embodiments, the non-metal component comprises a polymeric material. In some embodiments, the non-metal component comprises a semiconducting material. In some embodiments, the non-metal surface of the substrate comprises a dielectric material. In some embodiments, the non-metal surface comprises at least one of HfO₂, ZrO₂, HfAlOₓ, HfSiOₓ, Al₂O₃, SiCN, SiOC, SiOCN, or any combination thereof. In some embodiments, the non-metal surface comprises at least one of silicon dioxide (SiO₂), silicon oxycarbide, aluminum oxide, silicon nitride, tantalum nitride, titanium nitride, aluminum nitride, or any combination thereof.

In some embodiments, exposing the substrate proceeds at a temperature of 100° C. to 400° C., or any range or subrange between 100° C. to 400° C. In some embodiments, exposing the substrate proceeds at a temperature of 100° C. to 380° C., 100° C. to 360° C., 100° C. to 340° C., 100° C. to 320° C., 100° C. to 300° C., 100° C. to 280° C., 100° C. to 260° C., 100° C. to 240° C., 100° C. to 220° C., 100° C. to 200° C., 100° C. to 180° C., 100° C. to 160° C., 100° C. to 140° C., or 100° C. to 120° C. In some embodiments, exposing the substrate proceeds at a temperature of 120° C. to 400° C., 140° C. to 400° C., 160° C. to 400° C., 180° C. to 400° C., 200° C. to 400° C., 220° C. to 400° C., 240° C. to 400° C., 260° C. to 400° C., 280° C. to 400° C., 300° C. to 400° C., 320° C. to 400° C., 340° C. to 400° C., 360° C. to 400° C., or 380° C. to 400° C.

In some embodiments, exposing proceeds at a pressure of 0.1 Torr to 50 Torr, or any range or subrange between therebetween. In some embodiments, the pressure is a pressure in a range of 0.1 Torr to 45 Torr, 0.1 Torr to 40 Torr, 0.1 Torr to 35 Torr, 0.1 Torr to 30 Torr, 0.1 Torr to 25 Torr, 0.1 Torr to 20 Torr, 0.1 Torr to 15 Torr, 0.1 Torr to 10 Torr, 0.1 Torr to 5 Torr, 0.1 Torr to 1 Torr, 0.1 Torr to 0.2 Torr, 0.1 Torr to 50 Torr, 0.2 Torr to 50 Torr, 5 Torr to 50 Torr, 10 Torr to 50 Torr, 15 Torr to 50 Torr, 20 Torr to 50 Torr, 25 Torr to 50 Torr, 30 Torr to 50 Torr, 35 Torr to 50 Torr, 40 Torr to 50 Torr, or 45 Torr to 50 Torr.

In some embodiments, exposing the substrate to the inhibitor compound does not form a first layer on the non-metal surface of the substrate.

In some embodiments, heating, under vacuum, the substrate to a temperature sufficient to remove at least a portion of the inhibitor compound from the metal surface of the substrate.

At step 104, in some embodiments, the method 100 comprises exposing the substrate to a precursor material to from a second layer on a non-metal surface of the substrate.

In some embodiments, the exposing comprises contacting the substrate with the precursor material. In some embodiments, the contacting refers to bringing the substrate and the precursor material into close or immediate proximity. In some embodiments, the contacting refers to bringing the substrate and the precursor material into directly physical contact. In some embodiments, the exposing comprises introducing the precursor material into a chamber containing the substrate. In some embodiments, the exposing comprises pumping the precursor material from one location to a chamber containing the substrate. In some embodiments, the exposing comprises supplying the precursor material to the substrate. In some embodiments, the exposing comprises vaporizing the precursor material. In some embodiments, the exposing comprises flowing the precursor material from one location to a chamber containing the substrate. In some embodiments, the exposing comprises feeding the precursor material to a chamber containing the substrate. In some embodiments, exposing the substrate to the inhibitor compound comprises pulsing the precursor material into a chamber containing the substrate. In some embodiments, the precursor material comprises a precursor vapor. In some examples, exposing the substrate to the precursor vapor does not form a second layer on the metal surface of the substrate.

In some embodiments, exposing the substrate proceeds at a temperature of 100° C. to 400° C., or any range or subrange between 100° C. to 400° C. In some embodiments, exposing the substrate proceeds at a temperature of 100° C. to 380° C., 100° C. to 360° C., 100° C. to 340° C., 100° C. to 320° C., 100° C. to 300° C., 100° C. to 280° C., 100° C. to 260° C., 100° C. to 240° C., 100° C. to 220° C., 100° C. to 200° C., 100° C. to 180° C., 100° C. to 160° C., 100° C. to 140° C., or 100° C. to 120° C. In some embodiments, exposing the substrate proceeds at a temperature of 120° C. to 400° C., 140° C. to 400° C., 160° C. to 400° C., 180° C. to 400° C., 200° C. to 400° C., 220° C. to 400° C., 240° C. to 400° C., 260° C. to 400° C., 280° C. to 400° C., 300° C. to 400° C., 320° C. to 400° C., 340° C. to 400° C., 360° C. to 400° C., or 380° C. to 400° C.

In some embodiments, exposing proceeds at a pressure of 0.1 Torr to 50 Torr, or any range or subrange between therebetween. In some embodiments, the pressure is a pressure in a range of 0.1 Torr to 45 Torr, 0.1 Torr to 40 Torr, 0.1 Torr to 35 Torr, 0.1 Torr to 30 Torr, 0.1 Torr to 25 Torr, 0.1 Torr to 20 Torr, 0.1 Torr to 15 Torr, 0.1 Torr to 10 Torr, 0.1 Torr to 5 Torr, 0.1 Torr to 1 Torr, 0.1 Torr to 0.2 Torr, 0.1 Torr to 50 Torr, 0.2 Torr to 50 Torr, 5 Torr to 50 Torr, 10 Torr to 50 Torr, 15 Torr to 50 Torr, 20 Torr to 50 Torr, 25 Torr to 50 Torr, 30 Torr to 50 Torr, 35 Torr to 50 Torr, 40 Torr to 50 Torr, or 45 Torr to 50 Torr.

As mentioned above, the precursor materials may include any source precursor material, including vaporizable precursor materials. In some embodiments, the precursor material comprises, consists of, or consists essentially of, or is selected from the group consisting of, at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(diethylamino)tantalum (TBTDET), pentakis(dimethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the precursor material comprises, consists of, or consists essentially of, or is selected from the group consisting of, at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbony, or any combination therof.

In some embodiments, the precursor material comprises, consists of, or consists essentially of, or is selected from the group consisting of, at least one of elemental metal, metal halides, metal oxyhalides, metalorganic complexes, or any combination thereof. For example, in some embodiments, the precursor material comprises, consists of, or consists essentially of, or is selected from the group consisting of, at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In (CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor material comprises, consists of, or consists essentially of, or is selected from the group consisting of, at least one of any type of source material that can be liquefied either by heating or solubilization in a solvent including, for example and without limitation, at least one of decaborane, (B₁₀H1₄), pentaborane (B₅H₉), octadecaborane (B1₈H₂₂), boric acid (H₃BO₃), SbCl₃, SbCl₅, or any combination thereof. In some embodiments, the precursor material comprises, consists of, or consists essentially of, or is selected from the group consisting of, at least one of at least one of AsCl₃, AsBr₃, AsF₃, AsF₅, AsH₃, As₄O₆, As₂Se₃m As₂S₂, As₂S₃, As₂S₅, As₂Te₃, B₄H₁₁, B₄H₁₀, B₃H₆N₃, BBr₃, BCl₃, BF₃, BF₃·O(C₂H₅)₂, BF₃·HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiCl₄, SiH₃Cl, NH₃, NH₃, Ar, Br₂, HBr, BrF₅, CO₂, CO, COCl₂, COF₂, Cl₂, ClF₃, CF₄, C₂F₆, C₅F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PFS, SbH₃, SO₂, SF₆, SF₄, Si(OC₂H₅)₄, C₄H₁₆Si₄O₄, Si(CH₃)₄, SiH(CH₃)₃, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof.

In some embodiments, the solvent(s) is an organic solvent, an inorganic solvent, or any combination hereof. In some embodiments, the solvent(s) contains forms of arsenic, phosphorus, antimony, germanium, indium, tin, selenium, tellurium, fluorine, carbon, boron, aluminum, bromine, carbon, chlorine, nitrogen, silicon, tungsten, tantalum, ruthenium, selenium, nickel, sulfur, or any combination thereof. It will be appreciated that other precursor materials may be used herein without departing from this disclosure.

In some embodiments, the method further comprises removing at least a portion of the inhibitor compound from the metal surface of the substrate. In some embodiments, the removing comprises heating, under vacuum, the substrate to a temperature sufficient to remove at least a portion of the inhibitor compound from the metal surface of the substrate.

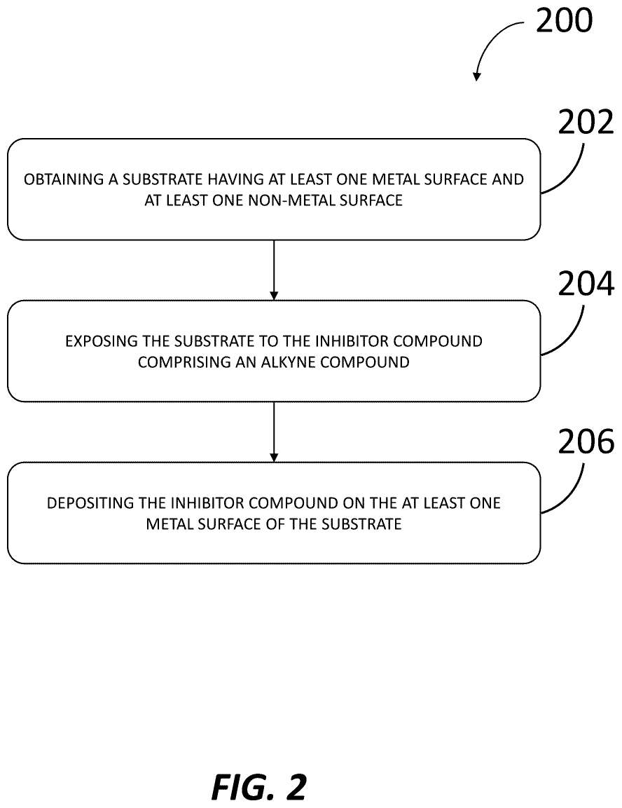

FIG. 2 is a flowchart of a method 200 for selectively depositing the inhibitor compound, according to some embodiments. As shown in FIG. 2, the method 200 for selectively depositing the inhibitor compound on a substrate comprises one or more of the following steps: obtaining a substrate having at least one metal surface and at least one non-metal surface; exposing the substrate to the inhibitor compound comprising an alkyne compound functionalized with at least one alkoxy group; and depositing the inhibitor compound on the at least one metal surface of the substrate.

### EXAMPLE

Inhibitor compounds disclosed herein were exposed to a substrate having a metal surface and a non-metal surface. The substrate was subsequently exposed to HfO₂ vapors for 1 s, 5 s, and 30 s. The control substrate was not exposed to the inhibitor compound but was exposed to HfO₂ vapor. A summary of the thicknesses (Å) of the resulting HfO₂ film on various substrates is presented in the table below.

| Substrate | Thickness (Å) | 1 s | 5 s | 30 s |
|---|---|---|---|---|
| Surface | No Inhibitor | exposure | exposure | exposure |
| SiO₂ | 28.1 | 8.9 | 8.1 | 4.4 |
| Cu | 24.6 | 0.8 | 0 | 0 |
| Mo | 31.5 | 11.6 | 9.3 | 5.6 |
| W | 27.6 | 2.3 | 0 | 0 |
| TiN | 27.9 | 6.9 | 7.8 | 2.3 |
| TaN | 24.4 | 4.5 | 4.4 | 0.8 |

As can be seen, the exposure of the substrate to the inhibitor compound substantially reduced the thickness of the HfO₂ film on metal surfaces or resulted in no deposition on the metal surfaces.

### ASPECTS

Various Aspects are described below. It is to be understood that any one or more of the features recited in the following Aspect(s) can be combined with any one or more other Aspect(s).

Aspect 1. A method comprising:
exposing a substrate to an inhibitor compound to form a first layer on a metal surface of the substrate,
   wherein the inhibitor compound comprises an alkyne compound functionalized with at least one alkoxy group; and exposing the substrate to a precursor vapor to form a second layer on a non-metal surface of the substrate.

Aspect 2. The method according to Aspect 1, wherein the inhibitor compound is a compound of the formula:

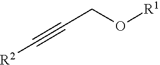

where:
   R¹ comprises at least one of a C₁-C₁₀ alkyl, a C₁-C₁₀ alkenyl, or a C₁-C₁₀ alkynyl, or any combination thereof;
   R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

Aspect 3. The method according to any one of Aspects 1-2, wherein the inhibitor compound is a compound of the formula:

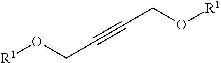

where:
   each R¹ independently comprises at least one of a C₁-C₁₀ alkyl, a C₁-C₁₀ alkenyl, or a C₁-C₁₀ alkynyl, or any combination thereof.

Aspect 4. The method according to any one of Aspects 1-3, wherein the inhibitor compound comprises at least one of the following compounds:

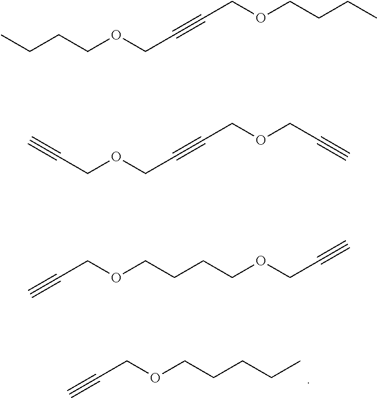

Aspect 5. The method according to any one of Aspects 1-4, wherein the metal surface of the substrate comprises at least one of copper, tungsten, cobalt, ruthenium, or any combination thereof.

Aspect 6. The method according to any one of Aspects 1-5, wherein the non-metal surface of the substrate comprises a dielectric material.

Aspect 7. The method according to any one of Aspects 1-6, wherein the non-metal surface comprises at least one of silicon dioxide (SiO₂), silicon oxycarbide, aluminum oxide, silicon nitride, tantalum nitride, titanium nitride, aluminum nitride, or any combination thereof.

Aspect 8. The method according to any one of Aspects 1-7, wherein exposing the substrate to the inhibitor compound comprises pulsing the inhibitor compound into a chamber containing the substrate.

Aspect 9. The method according to any one of Aspects 1-8, wherein the exposing proceeds at a temperature of 100° C. to 400° C.

Aspect 10. The method according to any one of Aspects 1-9, wherein the exposing proceeds at a pressure of 0.1 Torr to 50 Torr.

Aspect 11. The method according to any one of Aspects 1-10, wherein exposing the substrate to the inhibitor compound does not form a first layer on the non-metal surface of the substrate.

Aspect 12. The method according to any one of Aspects 1-11, wherein exposing the substrate to the precursor vapor does not form a second layer on the metal surface of the substrate.

Aspect 13. The method according to any one of Aspects 1-11, further comprising removing at least a portion of the inhibitor compound from the metal surface of the substrate.

Aspect 14. The method according to any one of Aspects 1-12, further comprising heating, under vacuum, the substrate to a temperature sufficient to remove at least a portion of the inhibitor compound from the metal surface of the substrate.

Aspect 15. A composition comprising:
an inhibitor compound,
   wherein the inhibitor compound comprises an alkyne compound functionalized with at least one alkoxy group;
   wherein the inhibitor compound in present in the composition at a purity of at least 95%;
   wherein the inhibitor compound is configured to selectively deposit a precursor vapor on a non-metal surface of a substrate.

Aspect 16. The composition according to Aspect 15, wherein the inhibitor compound is a compound of the formula:

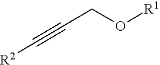

where:
   R¹ comprises at least one of a C₁-C₁₀ alkyl, a C₁-C₁₀ alkenyl, or a C₁-C₁₀ alkynyl, or any combination thereof.
   R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

Aspect 17. The composition according to any one of Aspects 15-16, wherein the inhibitor compound is a compound of the formula:

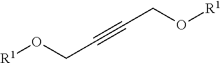

where:
   each R¹ independently comprises at least one of a C₁-C₁₀ alkyl, a C₁-C₁₀ alkenyl, or a C₁-C₁₀ alkynyl, or any combination thereof.

Aspect 18. The composition according to any one of Aspects 15-17, wherein the inhibitor compound comprises at least one of the following compounds:

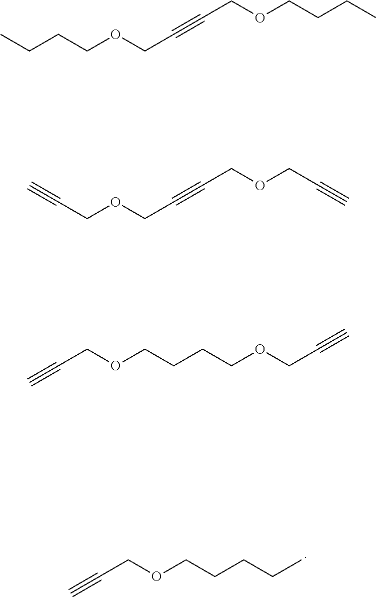

Aspect 19. The composition according to any one of Aspects 15-18, wherein the inhibitor compound in present in the composition at a purity of 95% to 99%.

Aspect 20. A vessel comprising the composition according to any one of Aspects 15-19.

Aspect 21. A method for selectively depositing an inhibitor compound, the method comprising:
obtaining a substrate having at least one metal surface and at least one non-metal surface;
exposing the substrate to the inhibitor compound comprising an alkyne compound functionalized with at least one alkoxy group; and
depositing the inhibitor compound on the at least one metal surface of the substrate.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
exposing a substrate to an inhibitor compound to form a first layer on a metal surface of the substrate,
wherein the inhibitor compound comprises an alkyne compound functionalized with at least one alkoxy group; and
exposing the substrate to a precursor vapor to form a second layer on a non-metal surface of the substrate.

2. The method of claim 1, wherein the inhibitor compound is a compound of the formula: 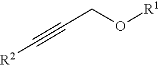
where:
R¹ comprises at least one of a C₁-C₁₀ alkyl, a C₁-C₁₀ alkenyl, or a C₁-C₁₀ alkynyl, or any combination thereof;
R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

3. The method of claim 1, wherein the inhibitor compound is a compound of the formula: 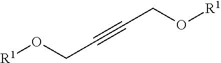
where:
each R¹ independently comprises at least one of a C₁-C₁₀ alkyl, a C₁-C₁₀ alkenyl, or a C₁-C₁₀ alkynyl, or any combination thereof.

4. The method of claim 1, wherein the inhibitor compound comprises at least one of the following compounds:

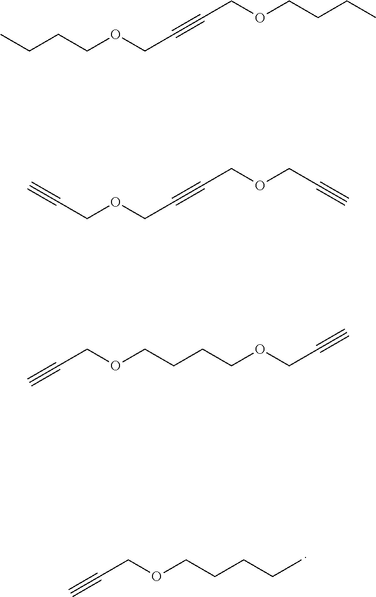

5. The method of claim 1, wherein the metal surface of the substrate comprises at least one of copper, tungsten, cobalt, ruthenium, or any combination thereof.

6. The method of claim 1, wherein the non-metal surface of the substrate comprises a dielectric material.

7. The method of claim 1, wherein the non-metal surface comprises at least one of silicon dioxide (SiO₂), silicon oxycarbide, aluminum oxide, silicon nitride, tantalum nitride, titanium nitride, aluminum nitride, or any combination thereof.

8. The method of claim 1, wherein exposing the substrate to the inhibitor compound comprises pulsing the inhibitor compound into a chamber containing the substrate.

9. The method of claim 1, wherein the exposing proceeds at a temperature of 100° C. to 400° C.

10. The method of claim 1, wherein the exposing proceeds at a pressure of 0.1 Torr to 50 Torr.

11. The method of claim 1, wherein exposing the substrate to the inhibitor compound does not form a first layer on the non-metal surface of the substrate.

12. The method of claim 1, wherein exposing the substrate to the precursor vapor does not form a second layer on the metal surface of the substrate.

13. The method of claim 1, further comprising removing at least a portion of the inhibitor compound from the metal surface of the substrate.

14. The method of claim 1, further comprising heating, under vacuum, the substrate to a temperature sufficient to remove at least a portion of the inhibitor compound from the metal surface of the substrate.

15. A composition comprising:
an inhibitor compound,
wherein the inhibitor compound comprises an alkyne compound functionalized with at least one alkoxy group;
wherein the inhibitor compound in present in the composition at a purity of at least 95%;
wherein the inhibitor compound is configured to selectively deposit a precursor vapor on a non-metal surface of a substrate.

16. The composition of claim 15, wherein the inhibitor compound is a compound of the formula: 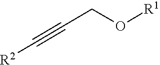
where:
R¹ comprises at least one of a C₁-C₁₀ alkyl, a C₁-C₁₀ alkenyl, or a C₁-C₁₀ alkynyl, or any combination thereof. R² comprises at least one of a hydrogen, a C₁-C₁₀ alkyl, a C₁-C₁₀ alkenyl, a C₁-C₁₀ alkynyl, a C₁-C₁₀ alkoxy, or any combination thereof.

17. The composition of claim 15, wherein the inhibitor compound is a compound of the formula: 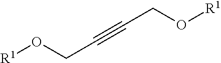
where:
each R¹ independently comprises at least one of a C₁-C₁₀ alkyl, a C₁-C₁₀ alkenyl, or a C₁-C₁₀ alkynyl, or any combination thereof.

18. The composition of claim 15, wherein the inhibitor compound comprises at least one of the following compounds:

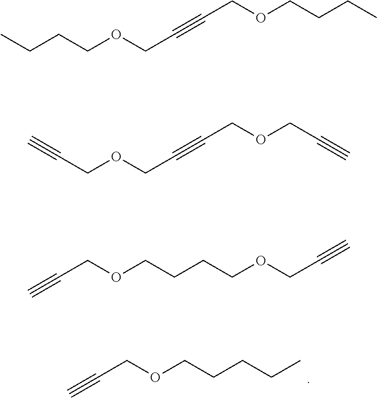

19. The composition of claim 15, wherein the inhibitor compound in present in the composition at a purity of 95% to 99%.

20. A method for selectively depositing an inhibitor compound, the method comprising:
obtaining a substrate having at least one metal surface and at least one non-metal surface;
exposing the substrate to the inhibitor compound comprising an alkyne compound functionalized with at least one alkoxy group; and
depositing the inhibitor compound on the at least one metal surface of the substrate.
